(19) United States
(12) Patent Application Publication
(10) Pub. No.: US 2012/0161236 A1
(43) Pub. Date: Jun. 28, 2012

(54) Electrostatic discharge protection device and manufacturing method thereof

(75) Inventors: Tsung-Yi Huang, Hsinchu City (TW); Jin-Lian Su, Fengshan Dist. (TW)

(73) Assignee: Richtek Technology Corporation, R.O.C.

(21) Appl. No.: 13/373,766

(22) Filed: Nov. 29, 2011

Related U.S. Application Data
(63) Continuation-in-part of application No. 13/317,323, filed on Oct. 15, 2011.

(30) Foreign Application Priority Data
Dec. 22, 2010 (TW) 099145374

(51) Int. Cl. H01L 29/78; H01L 21/336

(52) U.S. Cl. 257/355; 438/306; 257/E21.437; 257/E29.266

(57) ABSTRACT

The present invention discloses an electrostatic discharge protection device and a manufacturing method thereof. The electrostatic discharge protection device includes: a substrate, a gate, two N type lightly doped drains, an N type source, an N type drain, and two N type doped regions extending downward beneath and in contact with the source and drain respectively, such that when the source and drain are conducted with each other, at least part of the current flows through the two downwardly extending doped regions to increase the electrostatic discharge protection voltage of the electrostatic discharge protection device.

### CROSS REFERENCE

The present invention is a continuation-in-part of U.S. Ser. No. 13/317,323, filed on Oct. 15, 2011. The present invention also claims priority to TW 099145374, filed on Dec. 22, 2010.

### BACKGROUND OF THE INVENTION

1. Field of Invention

The present invention relates to an electrostatic discharge protection device and a manufacturing method thereof, in particular to such device having downwardly extending doped regions and a method for manufacturing the device.

2. Description of Related Art

FIGS. 1A-1E show, by cross-section view, a prior art N-type metal oxide semiconductor (MOS) device which is manufactured by the following steps: as shown in FIGS. 1A-1E, forming an isolation structure 12a and a P-type well 12b in a substrate 11 to define a device region 100; and forming a gate 13, a lightly doped drain 14, a source 15a and a drain 15b in the device region 100. The P-type well 12b can be the substrate 11 itself, and the gate 13 includes a gate dielectric layer 13a, a gate electrode layer 13b and a spacer layer 13c; the lightly doped drain 14, the drain 15b and the source 15a are formed by a lithography process and an ion implantation process, wherein the lithography process defines the implantation regions, and the ion implantation process implants N-type impurities to the defined regions. The N-type MOS device for example is an electrostatic discharge (ESD) protection device, that is, during test or in actual application, when the drain 15b receives high electrostatic voltage, a channel is formed in the ESD protection device to release or reduce the high electrostatic voltage, so as to protect other devices in the circuit. The protection ability of ESD protection device depends on the characteristic parameters of the device, which are often restricted by manufacturing parameters. In detail, it is often required for the ESD protection device to be integrated with a low voltage device in one substrate, and the high voltage device and the low voltage device should adopt the same manufacturing process steps with the same ion-implantation parameters, and thus the flexibility of the ion-implantation parameters for the ESD protection device is limited; as a result, the ESD protection device has a lower ESD protection voltage and a limited application range.

In view of above, to overcome the drawbacks in the prior art, the present invention proposes an ESD protection device and a manufacturing method thereof which provide a higher ESD protection voltage and a broader application range for the ESD protection device, in which additional manufacturing process steps are not required.

### SUMMARY OF THE INVENTION

The objectives of the present invention are to provide an electrostatic discharge protection device and its manufacturing method.

To achieve the foregoing objectives, from one perspective, the present invention provides an electrostatic discharge protection device, which is formed in a substrate, comprising: a gate on the substrate; a first conductive type source and a first conductive type drain at different sides below the gate; and two first conductive type downwardly extending doped regions extending downward beneath and in contact with the source and drain respectively, such that when the source and drain are conducted with each other, at least part of the current flows through the two downwardly extending doped regions to increase the electrostatic discharge protection voltage of the electrostatic discharge protection device.

In the foregoing electrostatic discharge protection device, a second conductive type device may be formed in the substrate, wherein the second conductive type device has a doped region having the same conductive type as the source and the drain, and the downwardly extending doped regions are formed by at least one common mask and doping process step of the doped region of the second conductive type device.

In the foregoing electrostatic discharge protection device, from cross-section view, one of the two downwardly extending doped regions has a width less than a width of the source and the other of the two downwardly extending doped regions has a width less than a width of the drain.

In another perspective of the present invention, it provides a method for manufacturing an electrostatic discharge protection device, comprising: providing a substrate; forming a gate on the substrate; forming a first conductive type source and a first conductive type drain at different sides below the gate; and forming two first conductive type downwardly extending doped regions extending downward beneath and in contact with the source and drain respectively, such that when the source and drain are conducted with each other, at least part of the current flows through the two downwardly extending doped regions to increase the electrostatic discharge protection voltage of the electrostatic discharge protection device.

In another perspective of the present invention, it provides an electrostatic discharge protection device, comprising: agate formed on the substrate; a first conductive type source and a first conductive type drain at different sides below the gate; at least one first conductive type downwardly extending doped region extending downward beneath and in contact with the source or the drain, such that when the source and drain are conducted with each other, at least part of the current flows through the downwardly extending doped region to increase the electrostatic discharge protection voltage of the electrostatic discharge protection device; and a first conductive type buried layer, beneath and in contact with the downwardly extending doped region; wherein when there are two downwardly extending doped regions respectively beneath and in contact with the source and the drain, the buried layer is in contact with only one of the downwardly extending doped region.

In yet another perspective of the present invention, it provides it provides a method for manufacturing an electrostatic discharge protection device, comprising: providing a substrate; forming a gate on the substrate; forming a first conductive type source and a first conductive type drain at different sides below the gate; forming at least one first conductive type downwardly extending doped region extending downward beneath and in contact with the source or the drain, such that when the source and drain are conducted with each other, at least part of the current flows through the downwardly extending doped region to increase the electrostatic discharge protection voltage of the electrostatic discharge protection device; and forming a first conductive type buried layer, beneath and in contact with the downwardly extending doped region; wherein when there are two downwardly extending doped regions respectively beneath and in contact with the source and drain, the buried layer is in contact with only one of the downwardly extending doped region.

In the foregoing electrostatic discharge protection device, preferably, a second conductive type device may be formed in the substrate, wherein the second conductive type device has a doped region having the same conductive type as the source and the drain, and the downwardly extending doped region is formed by at least one common mask and doping process step of the doped region of the second conductive type device.

In the foregoing electrostatic discharge protection device, preferably, from cross-section view, the downwardly extending doped region has a width less than a width of the source if the downwardly extending doped region is in contact with the source, or the downwardly extending doped region has a width less than a width of the drain if the downwardly extending doped region is in contact with the drain.

The objectives, technical details, features, and effects of the present invention will be better understood with regard to the detailed description of the embodiments below, with reference to the drawings.

### BRIEF DESCRIPTION OF THE DRAWINGS

FIG. 1A-1E show, by cross-section view, manufacturing process steps of a prior art N-type MOS device.

FIGS. 2A-2G show a first embodiment according to the present invention.

FIG. 3 shows another embodiment according to the present invention.

FIGS. 4-11 show several embodiments of another structure according to the present invention.

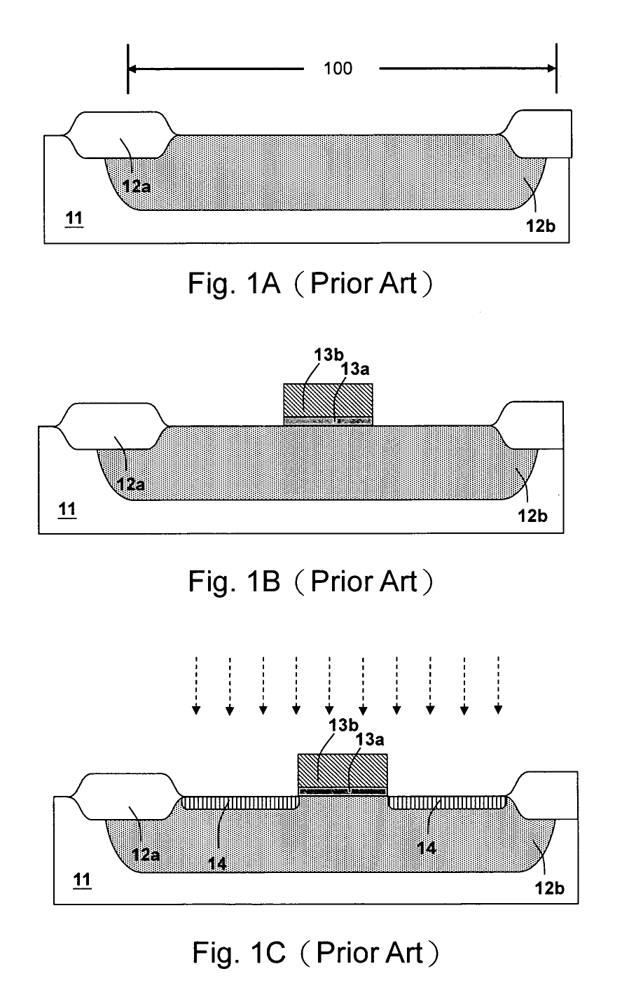

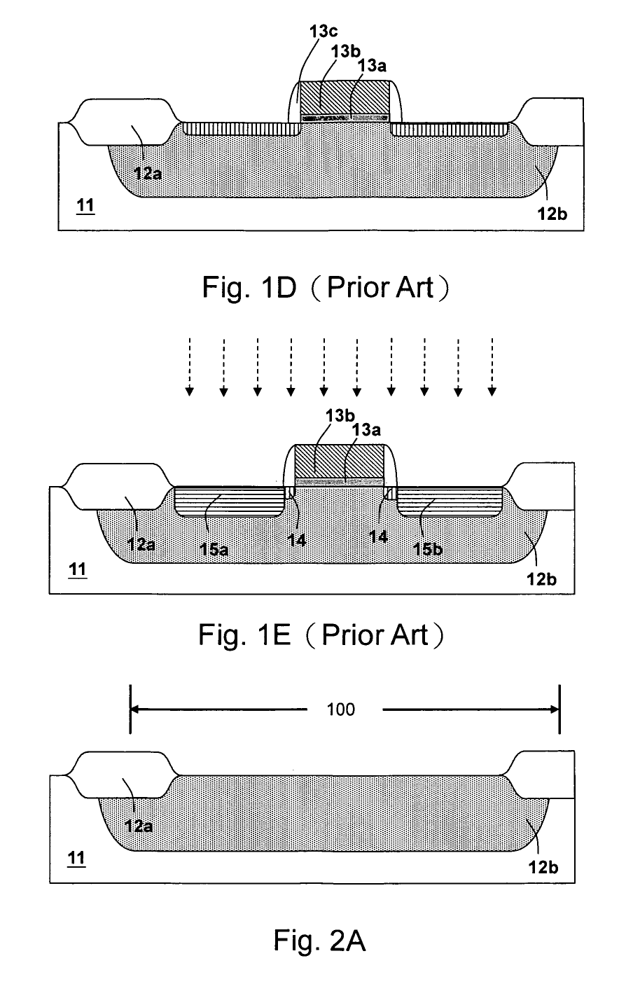

### DESCRIPTION OF THE PREFERRED EMBODIMENTS

The drawings as referred to throughout the description of the present invention are for illustration only, to show the interrelations between the regions and the process steps, but not drawn according to actual scale.

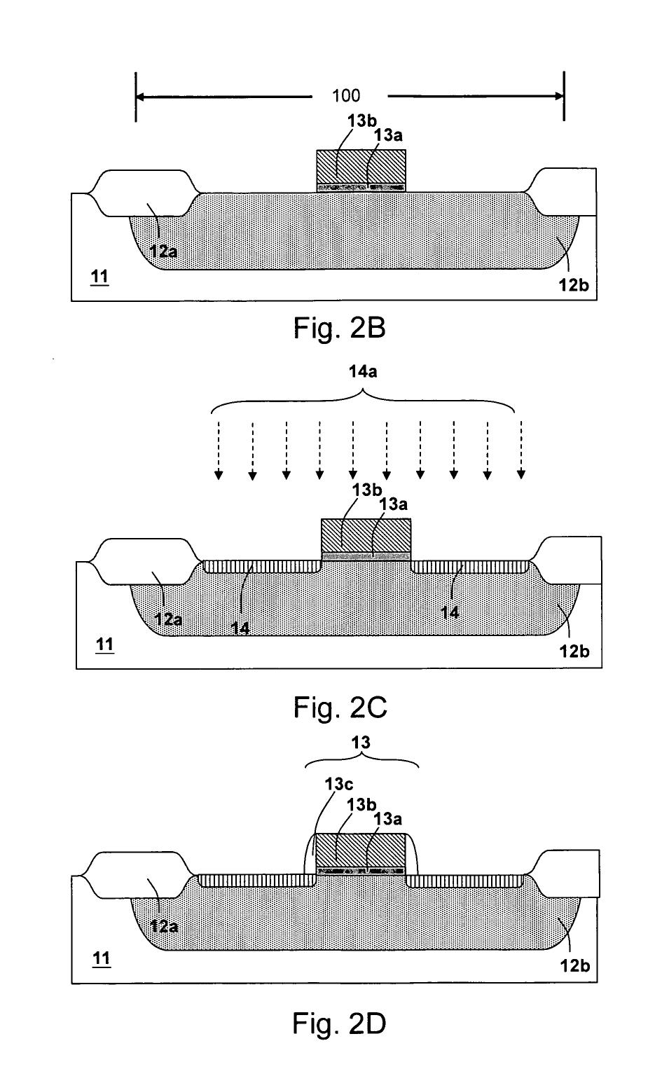

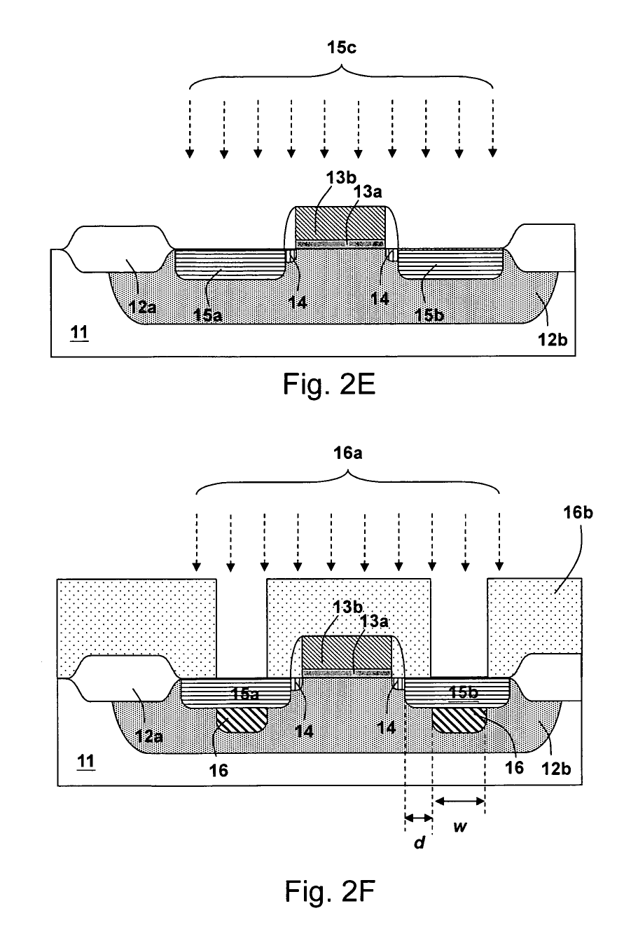

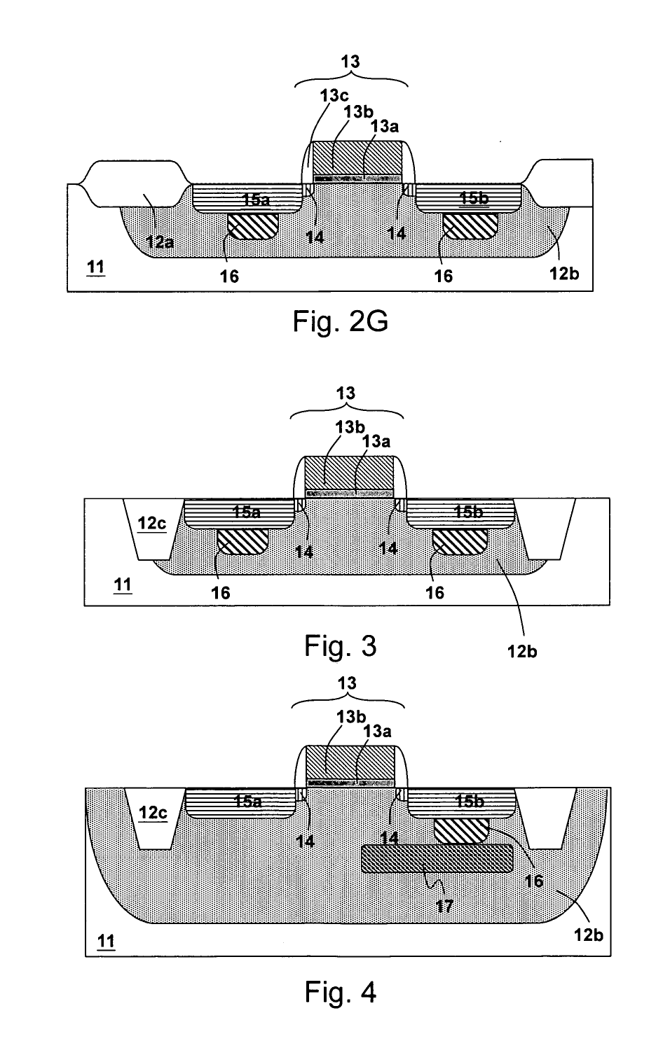

Please refer to FIGS. 2A-2G for a first embodiment according to the present invention, wherein an N-type ESD protection device is illustrated as an example. As shown in FIG. 2A, a substrate 11 is provided, in which is formed a P-type well 11 and an isolation structure 12a to define the device region 100, wherein the isolation structure 12a is, for example but not limited to, a local oxidation of silicon (LOCOS) structure as shown in the figure. Next, as shown in FIG. 2B, a gate dielectric layer 13a and a gate electrode layer 13b are defined in the device region 100 by lithography and etching.

Next, as shown in FIG. 2C, the isolation structure 12a and the gate electrode layer 13b are used as a mask, and N-type impurities are implanted into the substrate 11 to form two N-type lightly doped regions 14 at different sides below the gate electrode layer 13b as shown by the dashed arrows 14a illustrated in this figure.

Next, as shown in FIG. 2D, a spacer layer 13c is formed at the outer sides of the dielectric layer 13a and the gate electrode layer 13b by, for example but not limited to, thin film deposition and self-alignment etching, so that a gate 13 is formed.

Next, as shown in FIG. 2E, the source 15a and the drain 15b are formed under the surface of the substrate 11 in the device region 100 and at different sides below the gate 13 by a lithography process and an ion implantation process as shown by the dashed arrows 15a illustrated in this figure, wherein the lithography process defines the implantation regions by a photoresist mask together with a self-alignment effect provided by all or a part of the gate 13 and the isolation structure 12a, and the ion implantation process implants N-type impurities to form the source 15a and the drain 15b which are connected with the two N-type lightly doped regions 14 respectively. The source 15a and the drain 15b have heavier N-type impurity concentration than the two N-type lightly doped regions 14.

Next, as shown in FIG. 2F, two N-type downwardly extending doped regions 16 are formed by, for example but not limited to, a lithography process and an ion implantation process which implants N-type impurities to the substrate 11; the two N-type downwardly extending doped regions 16 are formed downward beneath and in contact with the source 15a and drain 15b respectively, such that when the source 15a and drain 15b are conducted with each other, part of the current flows through the two downwardly extending doped regions 16 to increase the ESD protection voltage of the ESD protection device. In this embodiment as shown in FIG. 2F, a photoresist layer 16b is used as a mask, and N-type impurities are implanted into the substrate 11 as shown by the dashed arrows 16a illustrated in this figure.

When the ESD protection device in this embodiment is integrated with another device in one substrate an that other device also has an N-type region (the device can be, for example but not limited to, a P-type device, and the N-type region can be, for example, an N-type well or an N-type anti-tunneling effect region), the two N-type downwardly extending doped regions 16 can be formed together with the N-type region of that other device by a common mask and doping process steps so that no additional mask or process steps are required. Thus, the ESD protection device in the present invention can be manufactured by a low cost.

Still referring to FIG. 2F, from cross-section view, one of the two downwardly extending doped regions 16 has a width w less than the width of the drain 15b, and there is a predetermined length d between the boundary of the downwardly extending doped region 16 and the boundary of the drain 15b which is closer to the gate 13. The other of the two downwardly extending doped regions 16 also has a width less than the width of the source 15a. The width w and the predetermined length d are set to prevent the length of the channel between the two N-type lightly doped regions 14 from being reduced by the two downwardly extending doped regions 16, to avoid changing the characteristics of the device other than the ESD protection voltage.

FIG. 2G shows a cross-section view of this embodiment after the above manufacturing process steps are performed. As shown in FIG. 2G, the ESD protection device in this embodiment is finished after the photoresist layer 16b is removed.

An N-type device is illustrated as an example in the above embodiment, but the same concept is certainly applicable to a P-type device.

FIG. 3 shows another embodiment according to the present invention. Different from the first embodiment, the isolation structure is a shallow trench isolation (STI) structure 12c in this embodiment.

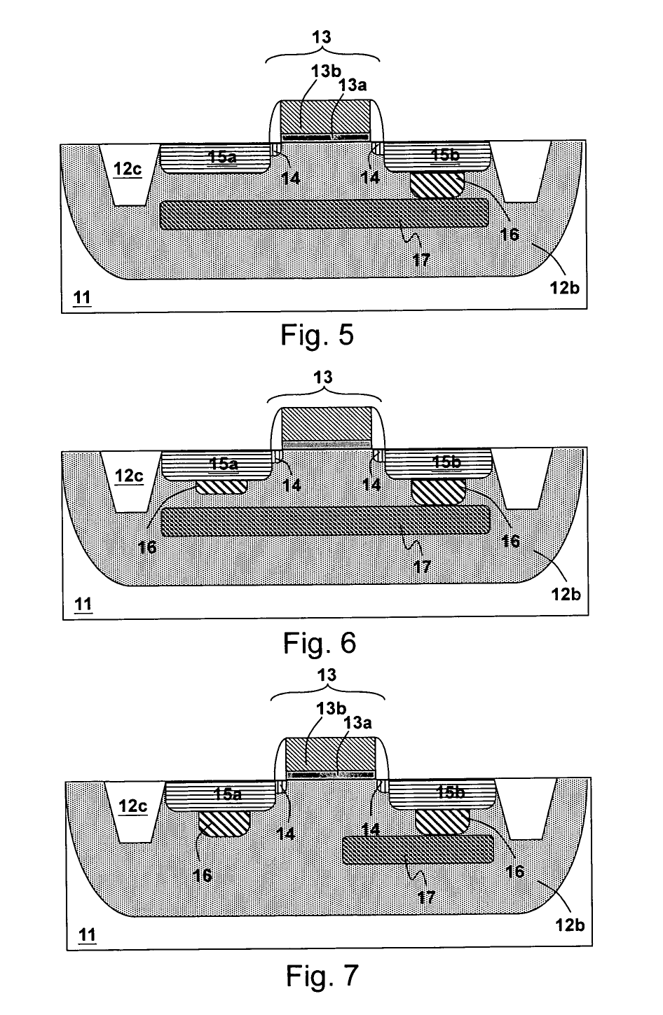

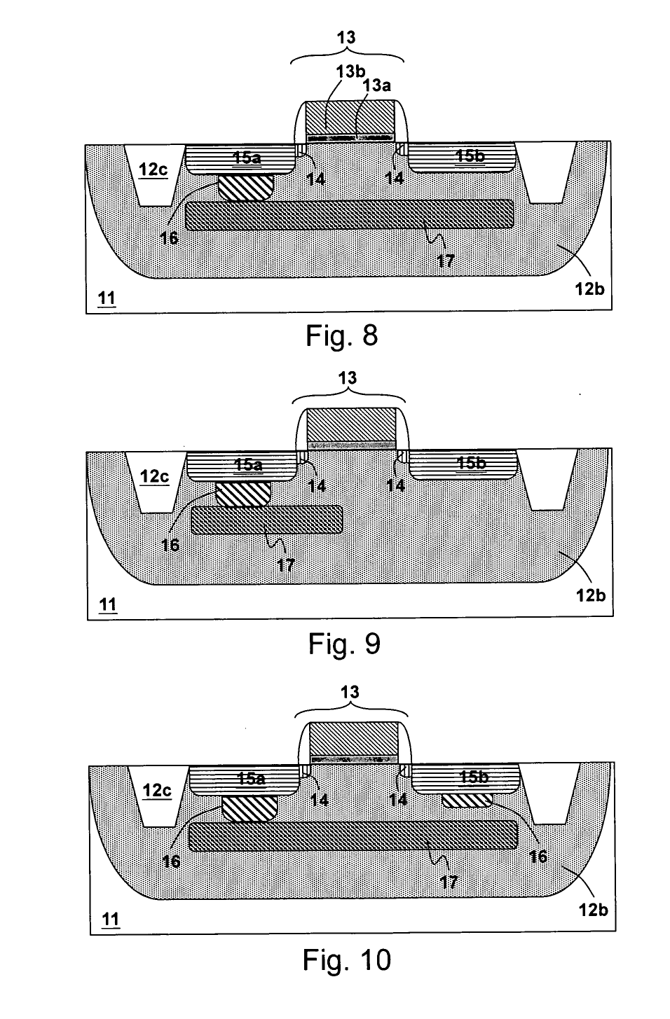

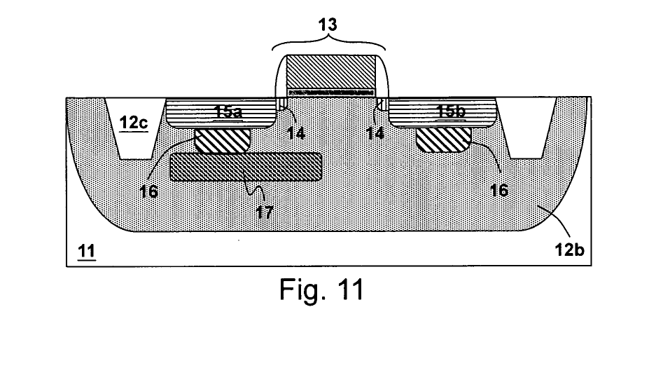

FIGS. 4-11 show several embodiments of another structure according to the present invention. These embodiments are different from the aforementioned embodiments in that, the ESD protection devices of this structure further include a buried layer 17 with the same conductive type (for example but not limited to the N-type) as the source 15a and drain 15b, beneath and in contact with the downwardly extending doped region 16 as shown in FIGS. 4-11. The downwardly extending doped region 16 may be formed beneath only one of the source 15a and the drain 16b. For example, the downwardly extending doped regions 16 shown in FIGS. 4 and 5 are formed beneath only the drains 15b; for another example, the downwardly extending doped regions 16 shown in FIGS. 8 and 9 are formed beneath only the sources 15a. Or, the downwardly extending doped regions 16 may be formed beneath both the source 15a and 15b as shown in FIGS. 6-7 and 10-11. Note that, when the downwardly extending doped regions 16 are formed beneath both the source 15a and drain 15b, the buried layer 17 should be in contact with only one of the downwardly extending doped regions 16. To avoid the contacts between the buried layer 17 and both the downwardly extending doped regions 16, the structure can be arranged such as: reducing the downward depth of one of the downwardly extending doped regions 16 beneath the source 15a and drain 15b as shown in FIGS. 6 and 10, or reducing the horizontal length of the buried layer 17 as shown in FIGS. 7 and 11. The above are just non-limiting examples; the present invention can be embodied in other ways to avoid the contacts between the buried layer 17 and both the downwardly extending doped regions 16, and all such variations are within the spirit of the present invention.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other manufacturing process steps or structures which do not affect the characteristics of the devices, such as a deep-well region, etc., can be added. As another example, the lithography process is not limited to photolithography; it can be electron beam lithography, X-ray lithography or other methods. As yet another example, if the ESD protection device of the present invention is manufactured in a wafer including other devices, the two N-type downwardly extending doped regions 16 not only can be formed by a common mask and process steps of the N-type well region or the N-type anti-tunneling effect region, but also can be formed by a mask and process steps for other purposes. Thus, the present invention should cover all such and other modifications and variations, which should be interpreted to fall within the scope of the following claims and their equivalents.

What is claimed is:

1. An electrostatic discharge protection device, comprising:
a gate formed on a substrate;
a first conductive type source and a first conductive type drain at different sides below the gate;
at least one first conductive type downwardly extending doped region extending downward beneath and in contact with the source or the drain, such that when the source and the drain are conducted with each other, at least part of the current flows through the downwardly extending doped region to increase the electrostatic discharge protection voltage of the electrostatic discharge protection device; and
a first conductive type buried layer, beneath and in contact with the downwardly extending doped region; wherein when there are two downwardly extending doped regions respectively beneath and in contact with the source and the drain, the buried layer is in contact with only one of the downwardly extending doped region.

2. The electrostatic discharge protection device of claim 1, wherein a second conductive type device is formed in the substrate, the second conductive type device having a doped region having the same conductive type as the source and drain, and the downwardly extending doped region is formed by at least one common mask and doping process step of the doped region of the second conductive type device.

3. The electrostatic discharge protection device of claim 1, wherein from cross-section view, the downwardly extending doped region has a width less than a width of the source if the downwardly extending doped region is in contact with the source, or the downwardly extending doped region has a width less than a width of the drain if the downwardly extending doped region is in contact with the drain.

4. A method for manufacturing an electrostatic discharge protection device, comprising:
providing a substrate;
forming a gate on the substrate;
forming a first conductive type source and a first conductive type drain at different sides below the gate;
forming at least one first conductive type downwardly extending doped region extending downward beneath and in contact with the source or the drain, such that when the source and the drain are conducted with each other, at least part of the current flows through the downwardly extending doped region to increase the electrostatic discharge protection voltage of the electrostatic discharge protection device; and
forming a first conductive type buried layer, beneath and in contact with the downwardly extending doped region; wherein when there are two downwardly extending doped regions respectively beneath and in contact with the source and the drain, the buried layer is in contact with only one of the downwardly extending doped region.

5. The method of claim 4, wherein a second conductive type device is formed in the substrate, the second conductive type device having a doped region having the same conductive type as the source and drain, and the downwardly extending doped region is formed by at least one common mask and doping process step of the doped region of the second conductive type device.

6. The method of claim 4, wherein from cross-section view, the downwardly extending doped region has a width less than a width of the source if the downwardly extending doped region is in contact with the source, or the downwardly extending doped region has a width less than a width of the drain if the downwardly extending doped region is in contact with the drain.
